(19) United States
(12) Patent Application Publication
(10) Pub. No.: US 2009/0108334 A1
(43) Pub. Date: Apr. 30, 2009

(54) Charge Trap Device and Method for Fabricating the Same

(75) Inventors: Moon Sig Joo, Icheon-si (KR); Seung Ho Pyi, Yongin-si (KR); Ki Seon Park, Yongin-si (KR); Yong Top Kim, Seoul (KR); Jae Young Park, Icheon-si (KR); Ki Hong Lee, Suwon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/164,720

(22) Filed: Jun. 30, 2008

(30) Foreign Application Priority Data
Oct. 31, 2007 (KR) 10-2007-0110490

(51) Int. Cl. H01L 21/28; H01L 29/792

(52) U.S. Cl. 257/326; 438/591; 257/E29.309; 257/E21.21

(57) ABSTRACT

A charge trapping device includes a plurality of isolation layers, a plurality of charge trapping layers, a blocking layer, and a control gate electrode. The isolation layers define active regions, and the isolation layers and active regions extend as respective stripes along a first direction on a semiconductor substrate. The charge trapping layers are disposed on the active regions in island forms where the charge trapping layers are separated from each other in the first direction and disposed on the respective active regions between the isolation layers in a second direction perpendicular to the first direction. The blocking layer is disposed on the isolation layers and the charge trapping layers. The control gate electrode is disposed on the charge trapping layer.

### CROSS-REFERENCE TO RELATED APPLICATION

Priority to Korean patent application number 10-2007-0110490, filed on Oct. 31, 2007, the disclosure of which is incorporated by reference in its entirety, is claimed.

### BACKGROUND OF THE INVENTION

The invention relates to a charge trap device (CTD) and, more particularly, to a CTD having advanced retention characteristics and a method for fabricating the same.

It is difficult for floating gate structures used in a non-volatile memory devices to meet the required performance of the non-volatile memory device because of the limited degree of integration of floating gate structures. Therefore, non-volatile memory devices with a charge trapping layer, i.e., a CTD, have gradually attracted much more interest. The CTD generally has a structure where a tunneling layer, a charge trapping layer, a blocking layer, and a control gate electrode are sequentially stacked on a substrate. Especially, the CTD may have a silicon-oxide-nitride-oxide-silicon (SONOS) structure where an oxide film and a polysilicon film are used as the blocking layer and the control gate electrode, respectively. The CTD may also have a metal-Al₂O₃-nitride-oxide-silicon (MANOS) structure where an aluminum oxide (Al₂O₃) film and a metal film are used as the blocking layer and the control gate electrode, respectively.

FIG. 1 illustrates a plan view of a typical CTD. FIG. 2 illustrates a sectional view taken along line II-II′ of FIG. 1. FIG. 3 illustrates a sectional view taken along line III-III′ of FIG. 1. Referring to FIGS. 1 to 3, isolation layers 102 are disposed in respective device isolation regions of a substrate 100. Active regions 104 of the substrate 100 are defined by the isolation layers 102. A tunneling layer 110 is disposed on the substrate 100. A gate stack 200 is disposed on the tunneling layer 110. The gate stack has a structure where a charge trapping layer 120, a blocking layer 130, a control gate electrode 140, and a word line 150 are sequentially stacked.

The charge trapping layers 120 are patterned perpendicular to the word lines 150 (in a sectional view taken along line II-II′ of FIG. 1), as shown in FIG. 2. In contrast, the charge trapping layers 120 extend as stripes parallel to the word lines 150 (in a sectional view taken along line III-III′ of FIG. 1), as shown in FIG. 3. Therefore, charges 202 in FIG. 3 stored in a cell thorough trap sites in the charge trapping layer 120 can move to a portion of the charge trapping layer on the trench isolation layer 102 as indicated by an arrow 204 in FIG. 3. The charges 202 in FIG. 3 may also move to a portion of the charge trapping layer 120 of an adjacent cell, as indicated by an arrow 206 in FIG. 3. This may cause charge loss, and thus a retention characteristic, i.e., data-storing capability, of a device can be adversely affected.

In addition, the charge trapping layer 120 serves to store charges flowing from a channel region through the tunneling layer 110 under predetermined conditions. The charge trapping layer 120 is generally formed of silicon-rich silicon nitride having high silicon-dangling bond. However, in this case, charge loss may occur due to the formation of a continuous conductive line of saturated silicon phases, and horizontal charge loss may occur due to a charge hopping phenomenon caused by a high trap density. Consequently, a retention characteristic, i.e. data-storing capability, of a device may be adversely affected.

### SUMMARY OF THE INVENTION

In one embodiment of the invention, a charge trapping device comprises: a plurality of isolation layers defining a plurality of active regions, said isolation layers separating said active regions from each other, and said isolation layers and said active regions extending respectively as stripes along a first direction on a semiconductor substrate; a plurality of charge trapping layers disposed on the active regions in the form of islands, wherein the charge trapping layers are separated from each other in the first direction and disposed on the respective active regions and extend in a second direction perpendicular to the first direction; a blocking layer disposed on the isolation layers and the charge trapping layers; and a control gate electrode disposed on the charge trapping layer.

In another embodiment of the invention, a method for fabricating a charge trapping device comprises: forming a tunneling layer on a substrate including a plurality of active regions defined by a plurality of isolation layers, said isolation layer and said active regions extending as respective stripes along a first direction in the substrate; forming a charge trapping layer on the tunneling layer; patterning the charge trapping layer in a second direction perpendicular to the first direction by removing portions of the charge trapping layer on the isolation layers; forming a blocking layer and a control gate electrode on the charge trapping layer and an exposed portion of the tunneling layer; and forming gate stacks separated from each other by patterning the control gate electrode, the blocking layer, and the charge trapping layer in the first direction.

### BRIEF DESCRIPTION OF THE DRAWINGS

FIG. 1 illustrates a plan view of a typical charge trap device (CTD).

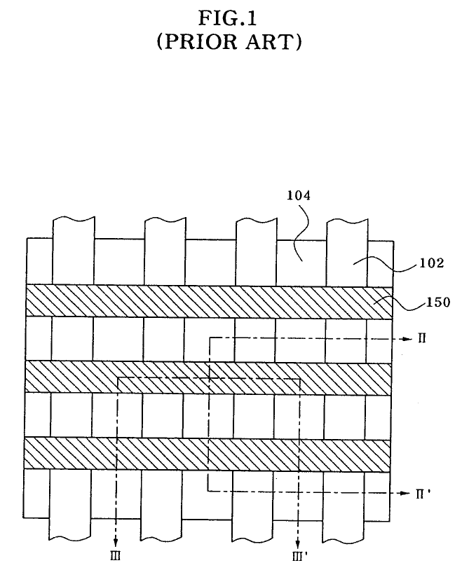

FIG. 2 illustrates a sectional view taken along line II-II′ of FIG. 1.

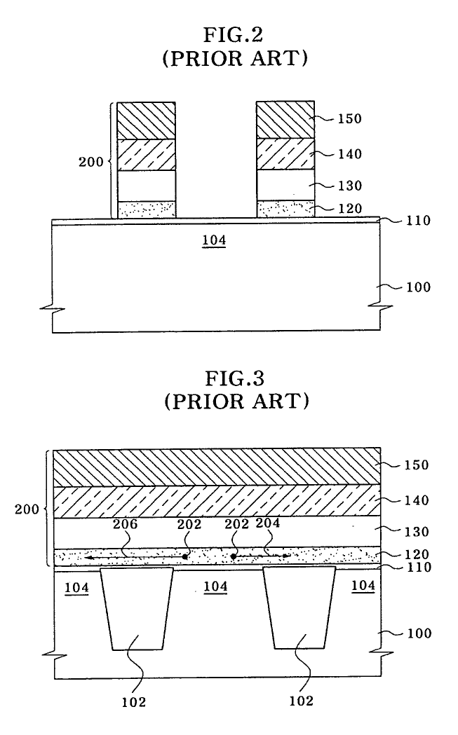

FIG. 3 illustrates a sectional view taken along line III-III′ of FIG. 1.

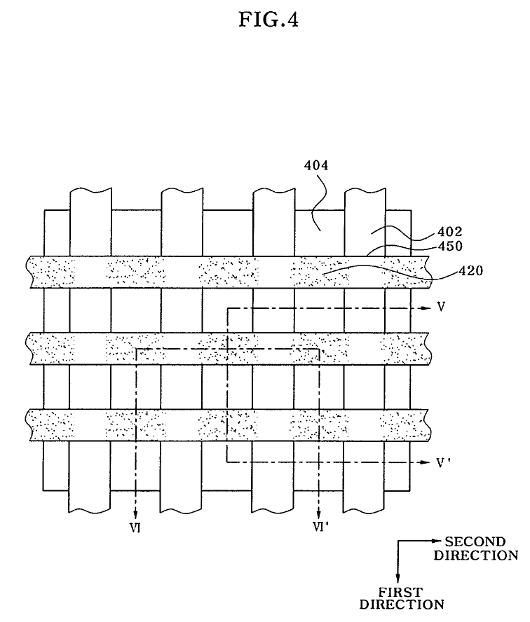

FIG. 4 illustrates a plan view of a CTD according to one embodiment of the invention.

FIG. 5 illustrates a sectional view taken along line V-V′ of FIG. 4.

FIG. 6 illustrates a sectional view taken along line VI-VI′ of FIG. 4.

FIGS. 7A, 8A and 9A illustrate a method for fabricating the CTD according to an embodiment of the invention, with sectional views taken along line V-V′ of FIG. 4.

FIGS. 7B, 8B and 9B illustrate a method for fabricating the CTD according to an embodiment of the invention, with sectional views taken along line VI-VI′ of FIG. 4.

### DESCRIPTION OF SPECIFIC EMBODIMENTS

Hereinafter, a charge trap device (CTD) and a method for fabricating the same in accordance with the invention is described in detail with reference to the accompanying drawings.

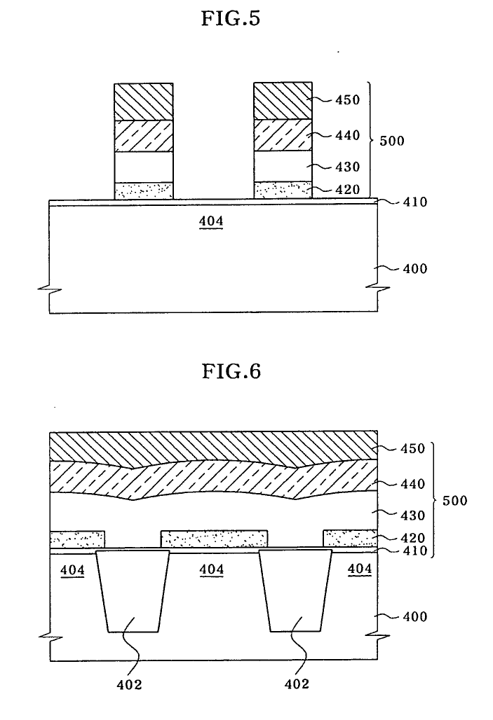

Referring to FIG. 4, isolation layers 402 are disposed in a substrate, in a stripe shape along a first direction. Accordingly, active regions 404 defined by the isolation layers are also disposed in a stripe shape along the first direction. In contrast, in a second direction substantially perpendicular to the first direction, the active regions 404 are separated from each other by the isolation layers 402. Charge trapping layers 420 are disposed on the active regions 404 of the substrate and are thus separated from each other in the first direction. The charge trapping layers 420 are disposed on the active regions 404, which are separated from each other by the isolation layers 402. Accordingly, the charge trapping layers 420 are not disposed on the isolation layers 402 in the first direction or in the second direction. Instead, the charge trapping layers 420 are configured as separate islands on the active regions. Word lines 450 are disposed in a stripe shape and overlap the charge trapping layers 420 in the second direction.

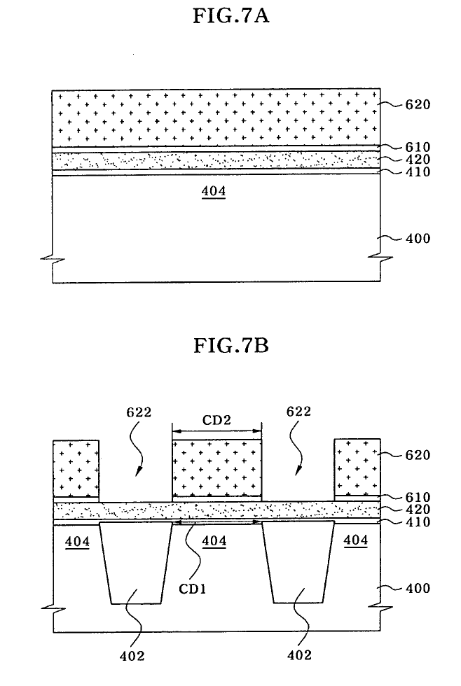

Referring to FIG. 5, the charge trapping layers 420 are disposed on the active region 404 of the substrate 400, respectively, and separated from each other. A tunneling layer 410 is interposed between the charge trapping layer 420 and the substrate 400. Blocking layers 430, control gate electrodes 440, and word lines 450 are sequentially stacked on the respective charge trapping layers 420 to form gate stacks 500.

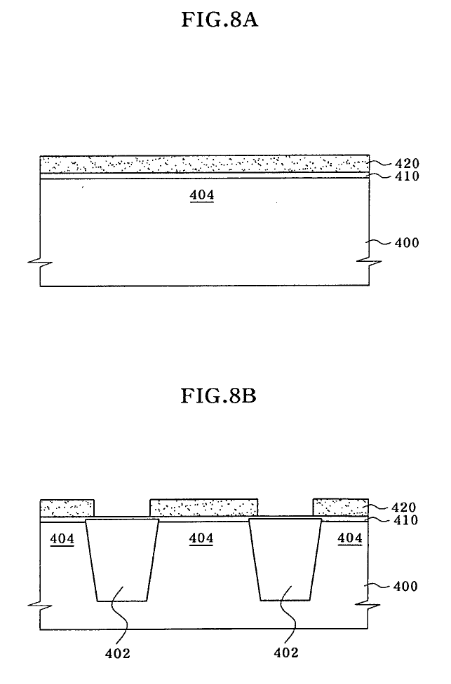

Referring to FIG. 6, the charge trapping layers 420 are disposed only on respective active regions 404 between the isolation layers 402, in the second direction parallel to the word line. Accordingly, on the active regions 404 between the isolation layers 402, a tunneling layer 410, charge trapping layers 420, a blocking layer 430, a control gate electrode 440, and a word line 450 are sequentially stacked. In contrast, on the isolation layer 402, a tunneling layer 410, a blocking layer 430, a control gate electrode 440, and a word line 450 are sequentially stacked.

As described above with reference to FIGS. 4 to 6, the charge trapping layers 420 of the CTD are separated from each other in the first direction perpendicular to the word line, and in the second direction parallel to the word line. Therefore, it is possible to prevent charges trapped in the charge trapping layer 420 from moving to adjacent charge trapping layers 420, whether in the first direction or in the second direction.

The tunneling layer 410 is preferably formed of oxide, preferably having a thickness from approximately 20 Å to approximately 60 Å. The charge trapping layer 420 is preferably formed of silicon nitride, preferably having a thickness from approximately 20 Å to approximately 100 Å. The charge trapping layer 420 is preferably formed of stoichiometric silicon nitride or silicon-rich silicon nitride. Alternatively, the charge trapping layer 420 may be formed of oxides, such as hafnium oxide (HfO₂), zirconium oxide (ZrO₂), hafnium aluminum oxide (HfAlO), hafnium silicon oxide (HfSiO), zirconium aluminum oxide (ZrAlO), or zirconium silicon oxide (ZrSiO), for example. The blocking layer 430 is preferably formed of aluminum oxide (Al₂O₃), preferably having a thickness from approximately 50 Å to approximately 300 Å. Alternatively, the blocking layer 430 may be formed of silicon oxide, preferably having a thickness from approximately 50 Å to approximately 100 Å, preferably using a chemical vapor deposition (CVD) method. The control gate electrode 440 is preferably formed of a metal, such as tantalum nitride (TaN), preferably having a work function of approximately 4.5 eV or higher. Alternatively, the control gate electrode 440 may be formed of polysilicon doped with n-type impurities at high concentration, for example, preferably at a concentration from approximately 1×10¹⁹ atoms/cm² to approximately 5×10²⁰ atoms/cm². A low resistance layer may be disposed on the control gate electrode 440 to lower a resistivity of the word line 450 as occasion demands. When the control gate electrode 440 is formed of a metal, the low resistance layer preferably comprises a polysilicon/tungsten nitride (WN)/tungsten silicide (WSi) film. When the control gate electrode 440 is formed of polysilicon, the low resistance layer preferably comprises a tungsten silicide (WSi) film or a tungsten nitride(WN)/tungsten silicide (WSi) film.

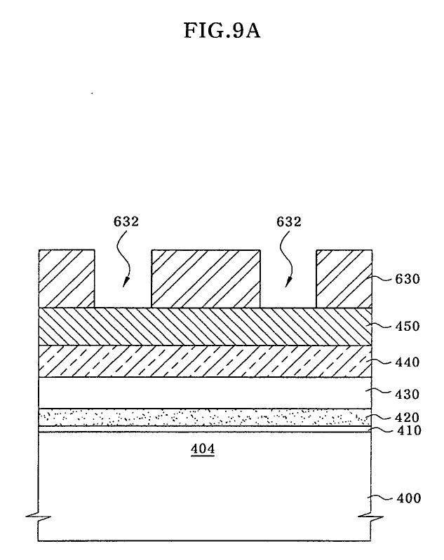

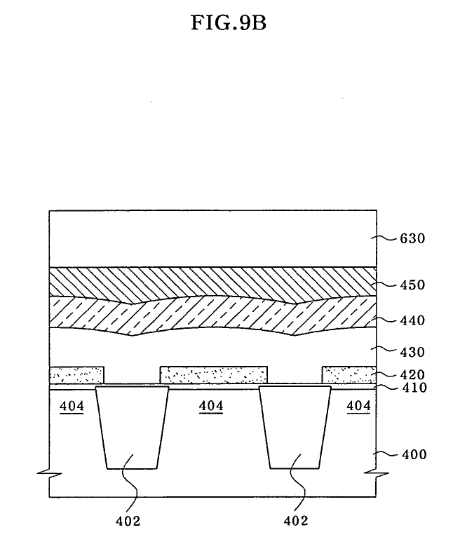

FIGS. 7A, 8A, and 9A and FIGS. 7B, 8B, and 9B illustrate a method for fabricating the CTD according to an embodiment of the invention. FIGS. 7A, 8A, and 9A illustrate the method, with sectional views taken along line V-V′ of FIG. 4. FIGS. 7B, 8B, and 9B illustrate the method, with sectional views taken along line VI-VI′ of FIG. 4.

Referring to FIGS. 7A and 7B, trench isolation layers 402 are formed in device isolation regions of a substrate 400 to define active regions 404. As described above with reference to FIG. 4, the trench isolation layers are formed in a stripe shape along a first direction. Accordingly, the active regions 404 defined by the isolation layers 402 are also formed in a stripe shape along the first direction, and separated from each other by the isolation layers 402 in a second direction. The trench isolation layers 402 are illustratively formed such that the active region 404 has a width CD1 smaller than a normal width to prevent misalign during a subsequent mask pattern forming operation. Thereafter, a tunneling layer 410 is formed. The tunneling layer 410 is preferably formed of an oxide, preferably to a thickness from approximately 20 Å to approximately 60 Å preferably using a thermal oxidation process or a radical oxidation process.

A charge trapping layer 420 is formed on the tunneling layer 410. The charge trapping layer 420 is preferably formed of a silicon nitride, preferably to a thickness from approximately 20 Å to approximately 100 Å. Alternatively, the charge trapping layer 420 may be formed of stoichiometric silicon nitride or silicon-rich silicon nitride, or of an oxide, such as hafnium oxide (HfO₂), zirconium oxide (ZrO₂), hafnium aluminum oxide (HfAlO), hafnium silicon oxide (HfSiO), zirconium aluminum oxide (ZrAlO), or zirconium silicon oxide (ZrSiO), for example. The charge trapping layer 420 is preferably formed by an Atomic Layer Deposition (“ALD”) method or a CVD method.

Next, an amorphous carbon film (or a bottom anti-reflection coating layer, as occasion demands) 610 and a mask pattern 620 are sequentially formed as a sacrificial layer, on the charge trapping layer 420. The mask pattern 620 is formed of a photoresist material. The mask pattern 620 illustratively has a width CD2 greater than the width CD1 of the active region 404 to secure a misalign margin. The film 610 serves to prevent the charge trapping layer 420 from being affected by residual materials after the removing of the photoresist layer in a subsequent process. The mask pattern 620 covers the entire film 610 in the first direction. On the contrary, in the second direction, the mask pattern 620 has openings 622 that expose a portion of the film 610. Then, an exposed portion of the film 610 is removed using the mask pattern 620. Consequently, in the second direction, a portion of the charge trapping layer 420 is exposed. Especially, a portion of the charge trapping layer 420 on the isolation layer 402 is exposed.

Referring to FIGS. 8A and 8B, an etching process is performed on the charge trapping layer 420 using the mask pattern 620 to remove the exposed portion of the charge trapping layer 420. Thereafter, the mask pattern in removed. The mask pattern 620 may be removed using a typical ashing process, for example. During the ashing process, the film 610 may also be removed. In a case where misalignment may occur during the forming of the mask pattern, an etch selectivity of the charge trapping layer 420 to the tunneling layer 410 is controlled to be at least 1:2 to prevent damage to the substrate 400. In a case where no misalignment occurs, the etch selectivity of the charge trapping layer 420 to the tunneling layer 410 is controlled to be at least 1:1. As shown in FIG. 8A, the charge trapping layer 420 is not patterned by the etching process in the first direction. On the contrary, as shown in FIG. 8B, the charge trapping layer 420 is patterned by the etching process in the second direction. Consequently, the charge trapping layer 420 is formed on a portion of the tunneling layer 410 overlapping the active region 404, however, is not formed on a portion of the tunneling layer 410 overlapping the isolation layer 402.

Referring to FIGS. 9A and 9B, a blocking layer 430 is formed on the charge trapping layers 420 and the tunneling layer 410 exposed between the trapping layers 420. Consequently, the blocking layer is formed on the charge trapping layers 420 in the first direction, whereas it is formed on the charge trapping layers 420 and the tunneling layer 410 overlapping the isolation layers 402. The blocking layer 430 is preferably formed of aluminum oxide (Al₂O₃), preferably to a thickness from approximately 50 Å to approximately 300 Å. Alternatively, the blocking layer 430 may be formed of silicon oxide, preferably to a thickness from approximately 50 Å to approximately 100 Å, preferably using a CVD method. In yet another alternative, the blocking layer 430 may be formed of a high-k material. After forming the blocking layer 430, a rapid thermal processing (RTP) is preferably performed for the purpose of densification.

Thereafter, a control gate electrode 440 is formed on the blocking layer 430. The control gate electrode 440 is preferably formed of polysilicon doped with n-type impurities at high concentration, for example at a concentration from approximately 1×10¹⁹ atoms/cm³ to approximately 5×10²⁰ atoms/cm³. Alternatively, the control gate electrode 440 may be formed of a metal, such as tantalum nitride (TaN), preferably having a work function of approximately 4.5 eV or higher. A word line 450 is formed on the control gate electrode 440. Before forming the word line 450, a low resistance layer is preferably formed on the control gate electrode 440 to reduce resistivity of the word line 450. If the control gate electrode 440 is formed of polysilicon, the low resistance layer preferably comprises a tungsten silicide (WSi) film, or a tungsten nitride (WN)/tungsten silicide (WSi) film. If the control gate electrode 440 is formed of a metal, the low resistance layer preferably includes a polysilicon/tungsten nitride (WN)/tungsten silicide (WSi) film. After that, a hard mask pattern 630 is formed on the word line 450. As shown in FIG. 9A, in the first direction, the hard mask pattern 630 has openings that expose a portion of the word line 450. On the contrary, in the second direction, the hard mask pattern 630 covers the entire word line 450.

After that, the exposed portion of the word line 450 is etched using the hard mask pattern 630 as an etch mask, and then portions of the control gate electrode 440, the blocking layer 430, and the charge trapping layer 420 that are sequentially exposed are also etched. As such, the CTD of FIGS. 5 and 6 is formed.

While the invention has been described with respect to the specific embodiments, various changes and modifications may be made without departing from the spirit and scope of the invention as defined in the following claims.

What is claimed is:

1. A charge trapping device, comprising:
a plurality of isolation layers defining a plurality of active regions, the isolation layers separating the active regions from each other, and the isolation layers and the active regions extending respectively as stripes along a first direction over a semiconductor substrate;
a plurality of charge trapping layers disposed on the active regions in the form of islands, wherein the charge trapping layers are separated from each other in the first direction and disposed on the respective active regions and extended in a second direction perpendicular to the first direction;
a blocking layer disposed on the isolation layers and the charge trapping layers; and
a control gate electrode disposed on the charge trapping layer.

2. The charge trapping device of claim 1, further comprising a tunneling layer interposed between the semiconductor substrate and the charge trapping layer, and between the isolation layer and the blocking layer.

3. A method for fabricating a charge trapping device, the method comprising:
forming a tunneling layer over a substrate including a plurality of active regions defined by a plurality of isolation layers, the isolation layer and the active regions extending as respective stripes along a first direction in the substrate;
forming a charge trapping layer over the tunneling layer;
patterning the charge trapping layer in a second direction perpendicular to the first direction by removing portions of the charge trapping layer on the isolation layers;
forming a blocking layer and a control gate electrode over the charge trapping layer and an exposed portion of the tunneling layer; and
forming gate stacks separated from each other by patterning the control gate electrode, the blocking layer, and the charge trapping layer in the first direction.

4. The method of claim 3, wherein the charge trapping layer comprises at least member of the group consisting of stoichiometric silicon nitride films and silicon-rich silicon nitride films.

5. The method of claim 3, wherein patterning the control gate electrode, the blocking layer, and the charge trapping layer comprises:
forming a sacrificial layer and a mask pattern on the charge trapping layer, the mask pattern having a plurality of openings that expose portions of the sacrificial layer on the respective isolation layers;
exposing portions of the tunneling layer on the respective isolation layers by removing the exposed portions of the sacrificial layer by etching using the mask pattern; and
removing the mask pattern and the sacrificial layer.

6. The method of claim 5, comprising etching process under conditions such that an etch selectivity of the charge trapping layer with respect to the tunneling layer is at least 1:2.

7. The method of claim 5, wherein the sacrificial layer comprises an amorphous carbon film.

8. The method of claim 5, wherein the sacrificial layer comprises a bottom anti-reflective coating layer.

9. The method of claim 3, wherein the blocking layer comprises an aluminum oxide film.

10. The method of claim 3, wherein the control gate electrode comprises a polysilicon film, a metal film, or combinations thereof.
